(19) United States
(12) Patent Application Publication
(10) Pub. No.: US 2007/0004148 A1
(43) Pub. Date: Jan. 4, 2007

(54) Multi-level cell of flash memory device

(75) Inventor: Hea Jong Yang, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor, Inc., Kyoungki-do (KR)

(21) Appl. No.: 11/477,227

(22) Filed: Jun. 28, 2006

(30) Foreign Application Priority Data
Jun. 30, 2005 (KR) 10-2005-57954
Jun. 14, 2006 (KR) 10-2006-53417

(51) Int. Cl. H01L 21/336; H01L 29/94

(52) U.S. Cl. 438/264; 257/296

(57) ABSTRACT

An embodiment of the present invention relates to a flash memory device with an improved data retention characteristic. A height of a floating gate is set lower than that of the conventional floating gate, or an overlap width between the floating gate and isolation structures is set narrower than those between the conventional isolation structures and floating gate. Accordingly, the surface area of the floating gate, which is influenced by mobile ion, can be reduced. It is therefore possible to improve a data retention characteristic in the flash memory cell.

### BACKGROUND

The present invention relates generally to the multi-level-cell flash memory device, and more particularly, to the multi-level-cell flash memory device with an improved data retention characteristic.

FIG. 1 is a graph showing threshold voltage (Vₜ) distributions of a single-level-cell (SLC) flash memory device. FIG. 2 is a graph showing threshold voltage distributions of a multi-level-cell (MLC) flash memory device. FIG. 3 is a graph showing variation in threshold voltage distributions of a SLC according to the retention test. FIG. 4 is a graph showing variation in threshold voltage distributions of a MLC according to the retention test.

As shown in FIGS. 1 and 2, in the case of the MLC, program states are divided into three unlike the SLC; e.g., the three states are “10,” “00,” and “01”. Accordingly, a width of cell threshold voltage distributions is narrow and read bias margin is also small.

In the SLC, if the elevated-temperature test process is performed at a temperature of 250° C. for 168 hours in order to test the data retention characteristic, the threshold voltage shifts about 0.3 V as shown in FIG. 3. There is also sufficient read margin that can discriminate program cells and erase cells.

In the case of the MLC, however, the threshold voltage of the program state “01” of the three program states shifts about 0.35 V after the retention test, as shown in FIG. 4. Read bias margin for discriminating the program states has decreased significantly, particularly between the program states “01” and “01.” This may result in a poor data retention characteristic.

It is believed that one of the reasons in which the threshold voltage shifts after the retention test in the MLC is mobile ions (e.g., Na+) contained in the insulating layer surrounding the floating gates.

In FIG. 5, a MLC flash memory device includes a semiconductor substrate 10, a tunnel oxide layer 11 over the substrate, a floating gate 12 over the tunnel oxide layer, an interlayer dielectric layer 13 over the floating gate, a control gate 15 over the interlayer dielectric layer.

If mobile ions with positive or negative charges are included in the insulating layer 16 around a programmed cell as shown in FIG. 5, they move near the floating gate 12 having an opposite charge during the backend process for the retention test, thus lowering a cell threshold voltage.

### SUMMARY OF THE INVENTION

An embodiment of the present invention relates to a MLC flash memory device with an improved data retention characteristic.

A flash memory device according to a first aspect of the present invention includes a semiconductor substrate in which isolation regions and active regions are defined, and a plurality of word lines to which flash memory cells in which a tunnel oxide film, a floating gate, a dielectric film, and a control gate are stacked on the active regions are connected. Isolation structures are formed in the isolation regions. A difference between a width of the word line and a height of the floating gate is in the range of 10 nm to 30 nm.

In the above, the height of the floating gate may be the same as a width or 20 nm or less larger than the width. The height of the floating gate may range from 800 Å to 1200 Å.

Furthermore, edges of the floating gate may be overlapped with the isolation structures about 22 nm to 28 nm.

A width of the floating gate, which corresponds to the width of the word line, may be larger than a gap between the word lines. The width of the floating gate may be within a range of 92 nm to 98 nm and the gap between the word lines may be within a range of 82 to 88 nm.

A channel length of the flash memory cell between the isolation structures may be in the range of 87 nm to 93 nm.

A flash memory device according to a second aspect of the present invention includes a semiconductor substrate in which isolation regions and active regions are defined, and a plurality of word lines to which flash memory cells in which a tunnel oxide film, a floating gate, a dielectric film, and a control gate are stacked on the active regions are connected. Isolation structures are formed in the isolation regions. A height of the floating gate ranges from 800 Å to 1200 Å.

In the above, edges of the floating gate may be overlapped with the isolation structures about 22 nm to 28 nm.

A flash memory device according to a third aspect of the present invention includes a semiconductor substrate in which isolation regions and active regions are defined, and a plurality of word lines to which flash memory cells in which a tunnel oxide film, a floating gate, a dielectric film, and a control gate are stacked on the active regions are connected. Isolation structures are formed in the isolation regions. Edges of the floating gate are overlapped with the isolation structures about 22 nm to 28 nm.

In the above, a channel length of the flash memory cell between the isolation structures may be in the range of 87 nm to 93 nm.

A width of the floating gate, which corresponds to a width of the word line, may be in the range of 92 nm to 98 nm. A gap between the word lines may be in the range of 82 nm to 88 nm.

The flash memory cell is a MLC capable of storing 2 bits or more.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a graph showing threshold voltage (Vₜ) distributions of a SLC flash memory device;

FIG. 2 is a graph showing threshold voltage distributions of a MLC flash memory device;

FIG. 3 is a graph showing variation in threshold voltage distributions of a SLC according to a retention test;

FIG. 4 is a graph showing variation in threshold voltage distributions of a MLC according to a retention test;

FIG. 5 is a view illustrating the influence of mobile ion in a general flash memory device;

FIG. 6 is a circuit diagram of a cell array of a flash memory device according to an embodiment of the present invention;

FIG. 7 is a layout diagram of the cell array shown in FIG. 6;

FIG. 8 is a cross-sectional view of the flash memory cell taken along line I-I′ in FIG. 7;

FIG. 9 is a cross-sectional view of the flash memory cell taken along line II-II′ in FIG. 7;

FIG. 10 is a conceptual view illustrating the structure of a floating gate shown in FIGS. 8 and 9; and

FIG. 11 is a characteristic graph showing in the shift of the threshold voltage values after the retention test was performed on the conventional flash memory cell and the flash memory cell according to an embodiment of the present invention.

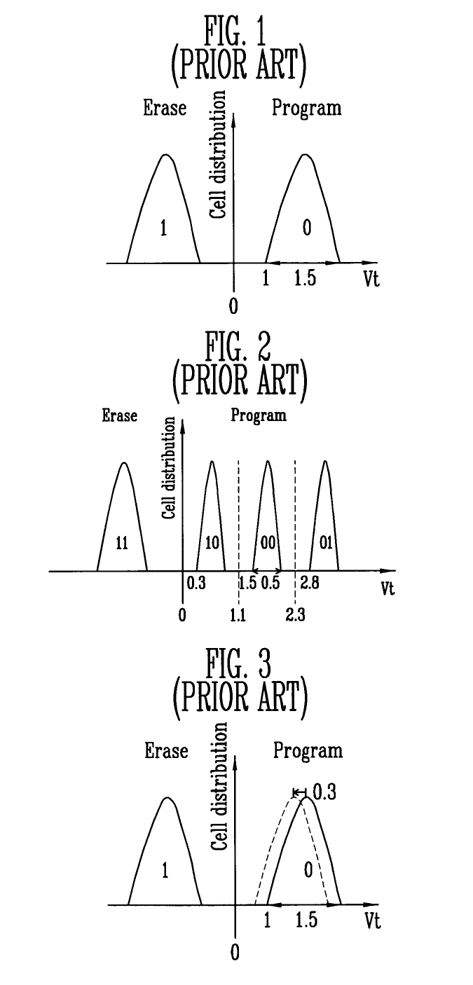

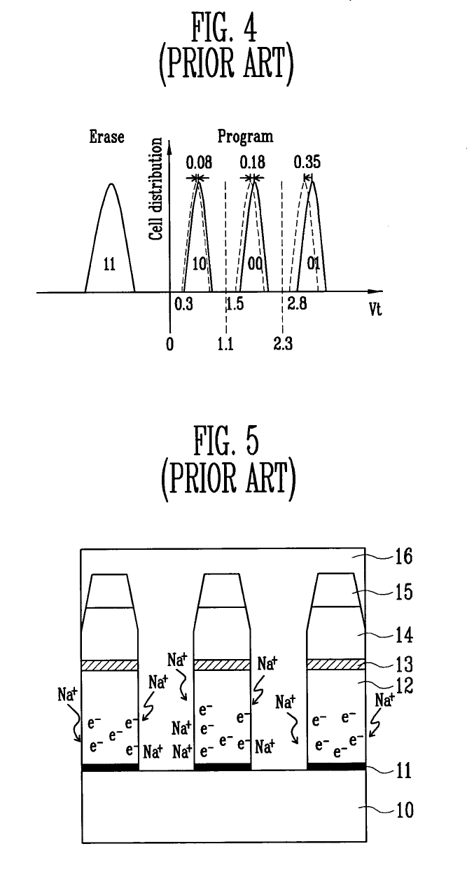

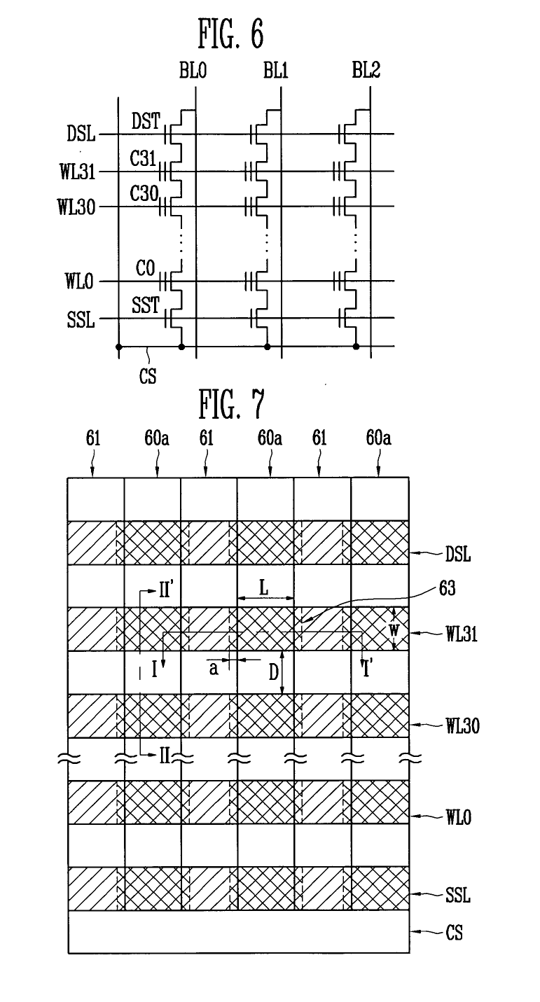

### DETAILED DESCRIPTION OF EMBODIMENTS

The present invention will now be described in detail in connection with certain exemplary embodiments with reference to the accompanying drawings.

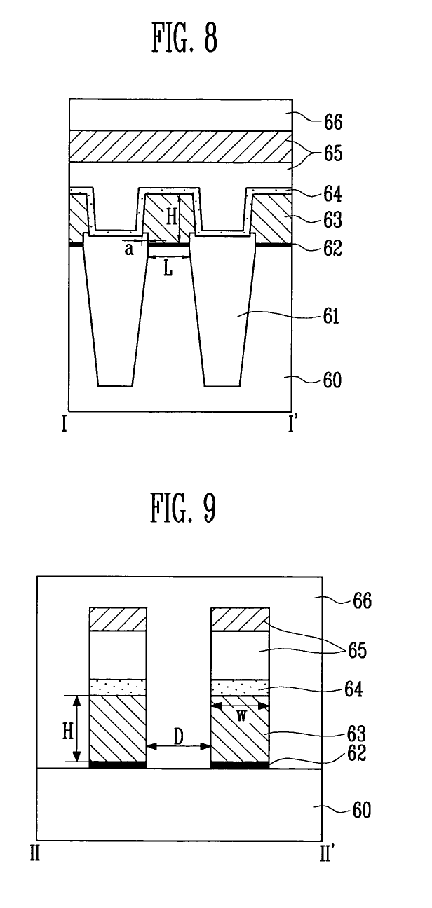

FIG. 6 is a circuit diagram of a cell array of a flash memory device according to an embodiment of the present invention, FIG. 7 is a layout diagram of the cell array shown in FIG. 6, FIG. 8 is a cross-sectional view of the flash memory cell taken along line I-I′ in FIG. 7, and FIG. 9 is a cross-sectional view of the flash memory cell taken along line II-II′ in FIG. 7.

Referring to FIG. 6, the NAND flash memory device according to an embodiment of the present invention includes a plurality of cell blocks. Each cell block includes a plurality of cell strings. The cell strings are connected between a common source CS and bit lines BL0, BL1, BL2, . . . , and include a drain select transistor DST, a source select transistor SST, and a plurality of flash memory cells C0 to C31. The plurality of flash memory cells C0 to C31 are connected between the drain select transistor DST and the source select transistor SST, the drain select transistor DST is connected to the bit lines, and the source select transistor SST is connected to the common source CS.

Furthermore, the gate of the drain select transistor DST included in each string is connected to become a drain select line DSL. The gate of the source select transistor SST included in each string is connected to become a source select line SSL. A plurality of word lines WL0 to WL31 are formed between the drain select line DSL and the source select line SSL. The number of the flash memory cells between the drain select transistor DST and the source select transistor SST may be 16, 32, 64 or more. The number of the word lines may be varied depending on the number of the flash memory cells.

Referring to FIGS. 7, 8, and 9, a plurality of isolation structures 61 are formed in a semiconductor substrate 60 in parallel in a bit line direction. The semiconductor substrates between the isolation structures 61 are defined as active regions 60a. The source select line SSL, the drain select line DSL, and the plurality of word lines WL0 to WL31 are formed in a vertical direction to the active regions 60a. The isolation structures 61 may have a Shallow Trench Isolation (STI) structure.

A tunnel oxide film 62, a floating gate 63, a dielectric film 64, and a control gate 65 are stacked on the active regions 60a of the semiconductor substrate 60, which cross the lines DSL, SSL, and WL0 to WL31. An interlayer insulation film 66 is then formed on the whole structure. The dielectric film 64 may have an ONO structure and the control gate 65 may have a stack structure of a polysilicon film and a tungsten silicide film. The edges of the floating gate 63 are overlapped with the isolation structures 61 so that a coupling ratio between the floating gate 63 and the control gate 65 are increased.

Both sides of the floating gate 63 are brought in contact with a spacer (not shown) or an insulating material, such as the interlayer insulation film 63. Therefore, the threshold voltage is varied under the influence of mobile ion, such as Na+, K+, Li+, and H+ contained in the insulating material. The mobile ion is generated during a wet etch or plasma etch process and is one of contaminants existing in the air.

Therefore, to minimize variation in the threshold voltage, it is required to reduce the influence by mobile ion. Furthermore, the influence of mobile ion can be reduced by controlling the surface area by changing the structure of the floating gate 63 contacting the insulating material. An example of changing the structure of the floating gate 63 in order to reduce the influence of mobile ion will be described below.

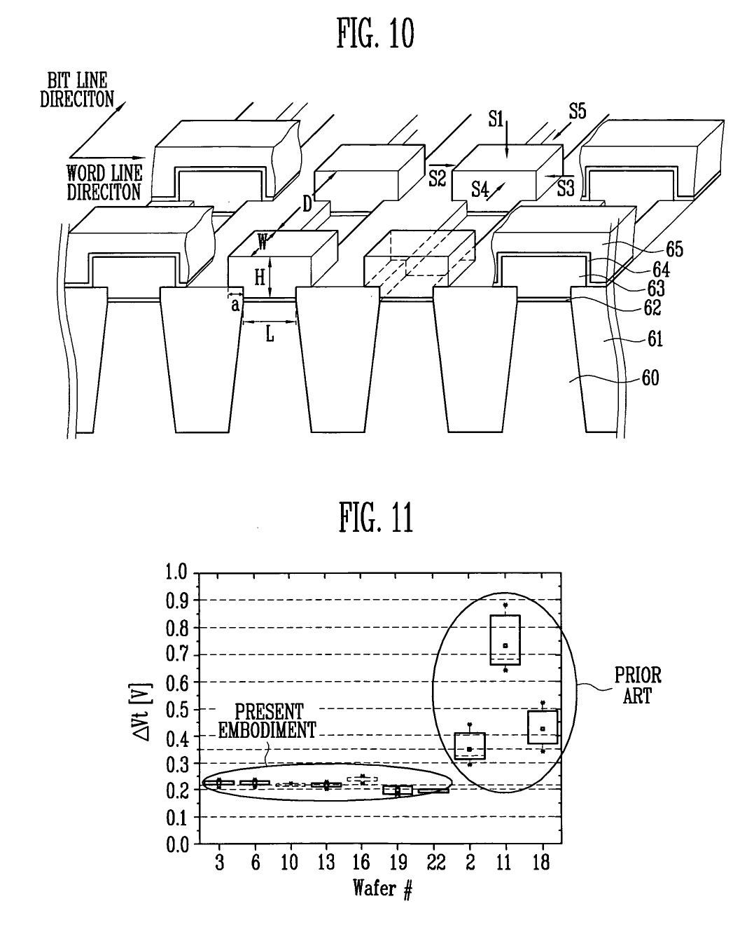

FIG. 10 is a conceptual view illustrating the structure of the floating gate shown in FIGS. 8 and 9.

Referring to FIG. 10, a top surface S1 and four sides S2 to S5 of the floating gate 63 are brought in contact with the insulating material. In more detail, the two sides S2 and S3 and the top surface S1 are brought in contact with the dielectric film 64 in the word line direction (more particularly, the two sides S2 and S3 and the top surface S1 are brought in contact with a lower insulating film of the dielectric film), and the two sides S4 and S5 are brought in contact with a spacer (not shown) or an insulating material, such as the interlayer insulation film 66, in the bit line direction.

In this case, the amount of mobile ion contained in the spacer or the interlayer insulation film 66 is greater than those in the dielectric film 64. It is therefore preferred that the surface area of the floating gate 63 and the sides S4 and S5, which are brought in contact with the interlayer insulation film 66, be reduced.

The surface area of the sides S4 and S5 of the floating gate 63 may be reduced by reducing an overlap width (a) of the floating gate 63 and the isolation structures 61, lowering a height (H) of the floating gate 63, reducing a channel length (L), or a combination of the three methods.

In this case, if the overlap width (a) of the floating gate 63 and the isolation structures 61 is reduced and the height (H) of the floating gate 63 is lowered, a coupling ratio between the floating gate 63 and the control gate 65 can be reduced. To compensate for the reduced coupling ratio, a width (W) of the floating gate 63 can be increased. As the width (W) of the floating gate 63 is increased, the width of the word line is increased.

At this time, an area occupied by the word line is increased and the degree of integration can be decreased accordingly. It is thus preferred that a gap (D) between the floating gates 63 be narrowed as much as the width (W) of the floating gate 63 is increased. As the gap (D) between the floating gates 63 is narrowed, the gap between the word lines is narrowed.

To minimize the influence by mobile ion, it is preferred that the overlap width (a), the height (H), the channel length (L), the width (W), and the gap (D) be set as listed in Table.

TABLE 1

| Subject | Values |
|---|---|
| Overlap width (a) | 22 nm to 28 nm (25 nm) |
| Height (H) | 800 Å to 1200 Å (1000 Å) |
| Channel length (L) | 87 nm to 93 nm (90 nm) |
| Width (W) | 92 nm to 98 nm (95 nm) |
| Gap (D) | 82 nm to 88 nm (85 nm) |

In Table 1, the values in the parentheses are the most preferred values when the design rule is 90 nm.

The following table 2 illustrates the comparison between the above values and values of a SLC.

TABLE 2

| | Flash memory cell of the | Conventional flash | |
|---|---|---|---|
| Subject | present invention | memory cell | |
| Overlap width (a) | 22 nm to 28 nm (25 nm) | 32 | nm |
| Height (H) | 800 Å to 1200 Å (1000 Å) | 1700 | Å |
| Channel length (L) | 87 nm to 93 nm (90 nm) | 100 | nm |
| Width (W) | 92 nm to 98 nm (95 nm) | 90 | nm |
| Gap (D) | 82 nm to 88 nm (85 nm) | 90 | nm |

In the same manner as the above, in the flash memory cell of the present invention, the surface area of both sides S4 and S5 of the floating gate, which are brought in contact with the interlayer insulation film, can be reduced by reducing the overlap width (a) of the floating gate, lowering the height (H), reducing the channel length (L), or a combination of the three methods in comparison with the conventional flash memory cell.

A coupling ratio, which is decreased as the overlap width (a), the channel length (L) or the height (H) reduced, can be compensated for by increasing the width (W) of the floating gate as much as about 2 nm to 8 nm. As the size is changed in order to reduce the surface area of the floating gate as described above, a difference between the height (H) and the width (W) is reduced to about 10 nm to 30 nm in comparison with the conventional flash memory cell (a SLC or a conventional MLC). More preferably, the size of the floating gate may be set such that the height (H) is the same as or greater than the width (W), but the size of the floating gate may be set so that a difference between the height (H) and the width (W) is 20 nm or less.

Meanwhile, in order to prevent the degree of integration from decreasing due to an increase of the width (W) of the floating gate, the gap (D) between the floating gates is reduced. In other words, as the width (W) of the floating gate increases, the gap (D) between the floating gates is reduced by about 2 nm to 8 nm. By changing the size of the floating gate as described above, the influence of mobile ion can be minimized and variation in the threshold voltage can be reduced.

FIG. 9 is a characteristic graph showing in the shift of the threshold voltage values after the retention test was performed on the conventional flash memory cell and the flash memory cell according to an embodiment of the present invention.

From FIG. 9, it can be seen that in the conventional MLC or SLC, the threshold voltage is shifted about 0.35 V or more due to mobile ion, whereas in the embodiment of the present invention in which the surface area of the floating gate, which is brought in contact with the interlayer insulation film, is reduced, the threshold voltage is shifted about 0.2 V. In other words, it can be seen that the amount of shift in the threshold voltage is improved about 0.15 V.

In the above, the MLC has been described as an example. However, in a SLC, if the size of the floating gate is changed in the same manner as the MLC, variation in the threshold voltage, which is incurred by mobile ion, can be reduced. This may lead to an improved data retention characteristic.

As described above, according to the present invention, variation in a cell threshold voltage is minimized by reducing the cross section of a floating gate in such a manner that the influence by mobile ion can be minimized while maintaining a coupling ratio with a control gate. Accordingly, the amount of shift in the threshold voltage can be reduced and a data retention characteristic of a flash memory cell can be improved.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A flash memory device comprising:
a semiconductor substrate in which isolation regions and active regions are defined, wherein isolation structures are formed in the isolation regions; and
a plurality of word lines to which flash memory cells in which a tunnel oxide film, a floating gate, a dielectric film, and a control gate are stacked on the active regions are connected,
wherein a difference between a width of the word line and a height of the floating gate is in the range of 10 nm to 30 nm.

2. The flash memory device of claim 1, wherein the height of the floating gate is the same as a width or 20 nm or less larger than the width.

3. The flash memory device of claim 2, wherein the height of the floating gate ranges from 800 Å to 1200 Å.

4. The flash memory device of claim 2, wherein edges of the floating gate are overlapped with the isolation structures about 22 nm to 28 nm.

5. The flash memory device of claim 1, wherein a width of the floating gate, which corresponds to the width of the word line, is larger than a gap between the word lines.

6. The flash memory device of claim 5, wherein the width of the floating gate is within a range of 92 nm to 98 nm and the gap between the word lines is within a range of 82 to 88 nm.

7. The flash memory device of claim 1, wherein a channel length of the flash memory cell between the isolation structures is in the range of 87 nm to 93 nm.

8. The flash memory device of claim 1, wherein the height of the floating gate ranges from 800 Å to 1200 Å.

9. The flash memory device of claim 1, wherein edges of the floating gate are overlapped with the isolation structures about 22 nm to 28 nm.

10. The flash memory device of claims 1, wherein the flash memory cell is a multi-level cell.

11. A flash memory device comprising:
a semiconductor substrate in which isolation regions and active regions are defined, wherein isolation structures are formed in the isolation regions; and
a plurality of word lines to which flash memory cells in which a tunnel oxide film, a floating gate, a dielectric film, and a control gate are stacked on the active regions are connected,
wherein a height of the floating gate ranges from 800 Å to 1200 Å.

12. The flash memory device of claim 11, wherein edges of the floating gate are overlapped with the isolation structures about 22 nm to 28 nm.

13. The flash memory device of claim 11, wherein a channel length of the flash memory cell between the isolation structures is in the range of 87 nm to 93 nm.

14. The flash memory device of claim 11, wherein a width of the floating gate, which corresponds to a width of the word line, is in the range of 92 nm to 98 nm.

15. A flash memory device comprising:
a semiconductor substrate in which isolation regions and active regions are defined, wherein isolation structures are formed in the isolation regions; and
a plurality of word lines to which flash memory cells in which a tunnel oxide film, a floating gate, a dielectric film, and a control gate are stacked on the active regions are connected,
wherein edges of the floating gate are overlapped with the isolation structures about 22 nm to 28 nm.

16. The flash memory device of claim 15, wherein a channel length of the flash memory cell between the isolation structures is in the range of 87 nm to 93 nm.

17. The flash memory device of claim 15, wherein a width of the floating gate, which corresponds to a width of the word line, is in the range of 92 nm to 98 nm.

18. The flash memory device of claim 17, wherein a gap between the word lines is in the range of 82 nm to 88 nm.

19. The flash memory device of any one of claims 15, wherein the flash memory cell is a multi-level cell.
